(19) United States
(12) Patent Application Publication
(10) Pub. No.: US 2025/0343208 A1
(43) Pub. Date: Nov. 6, 2025

(54) DISPLAY APPARATUS

(71) Applicant: AUO Corporation, Hsinchu City (TW)

(72) Inventors: Yea-Ching Chen, Hsinchu City (TW); Teng-Yuan Kuo, Hsinchu City (TW)

(73) Assignee: AUO Corporation, Hsinchu City (TW)

(21) Appl. No.: 18/815,738

(22) Filed: Aug. 26, 2024

(30) Foreign Application Priority Data
May 2, 2024 (TW) 113116407

(51) Int. Cl. H01L 25/075

(52) U.S. Cl. CPC H01L 25/0753

(57) ABSTRACT

A display apparatus includes light-emitting element substrates. The light-emitting element substrates are spliced into a sphere. Each of the light-emitting element substrates includes a base and pixel structures. The light-emitting element substrates include a first light-emitting element substrate. The base of the first light-emitting element substrate is in an N-gonal shape. N is a positive integer greater than 4. A first edge and a second edge of the N-gonal shape are substantially parallel to two dummy meridians of the sphere respectively. A dummy reference line is located between the first edge and the second edge and is not parallel to the first edge and the second edge. The pixel structures of the first light-emitting element substrate include a pixel structure group. The light-emitting elements of the pixel structures of the pixel structure group are substantially arranged along a direction parallel to the dummy reference line.

### CROSS-REFERENCE TO RELATED APPLICATION

This application claims the priority benefit of Taiwan application serial no. 113116407, filed on May 2, 2024. The entirety of the above-mentioned patent application is hereby incorporated by reference herein and made a part of this specification.

### BACKGROUND

### Technical Field

The disclosure relates to an optoelectronic apparatus, and in particular relates to a display apparatus.

### Description of Related Art

The light-emitting diode display apparatus includes a circuit substrate and multiple light-emitting diode elements electrically connected to the circuit substrate. Inheriting the characteristics of light-emitting diodes, light-emitting diode display apparatuses have the advantages of power saving, high efficiency, high brightness, and fast response time. Additionally, compared with organic light-emitting diode display apparatuses, light-emitting diode display apparatuses also have the advantages of easy color adjustment, long light-emitting lifetime, and no image burn-in. Therefore, the light-emitting diode display apparatus is regarded as the next generation display technology.

The light-emitting diode display apparatus may include multiple light-emitting element substrates, in which the light-emitting element substrates may be spliced into a spherical shape to provide a spherical display. However, spherical display apparatuses usually include a variety of different light-emitting element substrates, which require high development costs. Moreover, when viewed from a large viewing angle, the light-emitting diode display apparatus is prone to color shift due to the fixed arrangement sequence, thereby affecting the display quality of the spherical light-emitting diode display apparatus.

### SUMMARY

A display apparatus with good display effect is provided in the disclosure.

A display apparatus of an embodiment of the disclosure includes multiple light-emitting element substrates. The light-emitting element substrates are spliced into a sphere, in which the sphere has multiple dummy latitudes and multiple dummy meridians. Each of the light-emitting element substrates includes a base and multiple pixel structures disposed on the base, in which each of the pixel structures includes multiple light-emitting elements for emitting different color lights. The light-emitting element substrates include a first light-emitting element substrate. The base of the first light-emitting element substrate is in an N-gonal shape. N is a positive integer greater than 4. The N-gonal shape has a first edge and a second edge. The first edge and the second edge are substantially parallel to two of the dummy meridians of the sphere respectively. A dummy reference line is located between the first edge and the second edge and is not parallel to the first edge and the second edge. The pixel structures of the first light-emitting element substrate include a pixel structure group. The light-emitting elements of the pixel structures of the pixel structure group are substantially arranged along a direction parallel to the dummy reference line.

A display apparatus of an embodiment of the disclosure includes multiple light-emitting element substrates spliced into a sphere, in which the sphere has multiple dummy latitudes and multiple dummy meridians. Each of the light-emitting element substrates includes a base and multiple pixel structures disposed on the base. Each of the pixel structures includes a first light-emitting element and a second light-emitting element respectively configured to emit a first color light and a second color light. The light-emitting element substrates include a first light-emitting element substrate. The pixel structures of the first light-emitting element substrate include multiple first pixel structures and multiple second pixel structures. The first light-emitting element and the second light-emitting element of each of the first pixel structures are arranged sequentially in a first meridian direction. The first light-emitting element and the second light-emitting element of each of the second pixel structures are arranged sequentially in a second meridian direction. The first meridian direction and the second meridian direction are substantially parallel to the dummy meridians, and the first meridian direction is opposite to the second meridian direction. The first pixel structures and the second pixel structures of the first light-emitting element substrate are arranged into multiple pixel rows. The first pixel structures and the second pixel structures in each of the pixel rows are alternately arranged in a latitude direction that is substantially parallel to the dummy latitudes. A sum of a number of the first pixel structures and a number of the second pixel structures in each of the pixel rows is an even number.

### BRIEF DESCRIPTION OF THE DRAWINGS

FIG. 1 is a schematic diagram of a display apparatus 10 of an embodiment of the disclosure.

FIG. 2 is an enlarged schematic diagram of a portion 10a of the display apparatus 10 of FIG. 1.

FIG. 3 is an enlarged schematic diagram of part r1 of a portion 10a of the display apparatus 10 of FIG. 2.

FIG. 4 is an enlarged schematic diagram of part r2 of a portion 10a of the display apparatus 10 of FIG. 2.

FIG. 5 is an enlarged schematic diagram of part r3 of a portion 10a of the display apparatus 10 of FIG. 2.

FIG. 6 is a schematic diagram of a light-emitting element substrate 100-1 of an embodiment of the disclosure.

FIG. 7 is a schematic diagram of a light-emitting element substrate 100-2 of an embodiment of the disclosure.

FIG. 8 is a schematic diagram of a light-emitting element substrate 100-3 of an embodiment of the disclosure.

FIG. 9 is a schematic diagram of various light-emitting element substrates of an embodiment of the disclosure.

FIG. 10 is a schematic diagram of a light-emitting element substrate 100-4 of an embodiment of the disclosure.

FIG. 11 is a schematic diagram of multiple light-emitting element substrates 100-2 of an embodiment of the disclosure.

FIG. 12 shows the relative brightness of the first color light, the second color light, and the third color light at various viewing angles of the display apparatus 10 of an embodiment of the disclosure.

FIG. 13 shows the relative brightness of the first color light, the second color light, and the third color light at various viewing angles of a display apparatus of a comparative example.

FIG. 14 is a schematic diagram of a light-emitting element substrate 100-1A of a display apparatus of another embodiment of the disclosure.

FIG. 15 is a schematic diagram of a light-emitting element substrate 100-1B of a display apparatus of yet another embodiment of the disclosure.

FIG. 16 is a schematic diagram of multiple light-emitting element substrates of a display apparatus of yet another embodiment of the disclosure.

### DETAILED DESCRIPTION OF DISCLOSED EMBODIMENTS

References of the exemplary embodiments of the disclosure are to be made in detail. Examples of the exemplary embodiments are illustrated in the drawings. If applicable, the same reference numerals in the drawings and the descriptions indicate the same or similar parts.

It should be understood that when an element such as a layer, a film, an area, or a substrate is indicated to be “on” another element or “connected to” another element, it may be directly on another element or connected to another element, or an element in the middle may exist. In contrast, when an element is indicated to be “directly on another element” or “directly connected to” another element, an element in the middle does not exist. As used herein, “to connect” may indicate to physically and/or electrically connect. Furthermore, “to electrically connect” or “to couple” may also be used when other elements exist between two elements.

The usages of “approximately”, “similar to”, or “substantially” indicated throughout the specification include the indicated value and an average value having an acceptable deviation range, which is a certain value confirmed by people skilled in the art, and is a certain amount considered the discussed measurement and measurement-related deviation (that is, the limitation of measurement system). For example, “approximately” may indicate to be within one or more standard deviations of the indicated value, or being within ±30%, ±20%, ±10%, ±5%. Furthermore, the usages of “approximately”, “similar to”, or “substantially” indicated throughout the specification may refer to a more acceptable deviation scope or standard deviation depending on optical properties, etching properties, or other properties, and all properties may not be applied with one standard deviation.

Unless otherwise defined, all terms (including technical and scientific terms) used herein have the same meaning as that commonly understood by one of ordinary skill in the art to which this disclosure belongs. It should be further understood that terms such as those defined in commonly used dictionaries should be construed as having meanings consistent with their meanings in the context of the related art and the disclosure, and are not to be construed as idealized or excessive formal meaning, unless expressly defined as such herein.

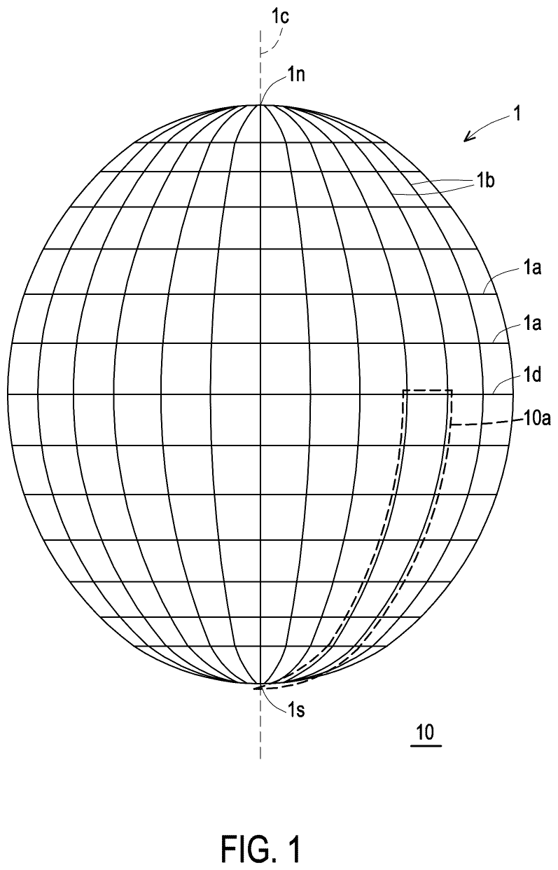

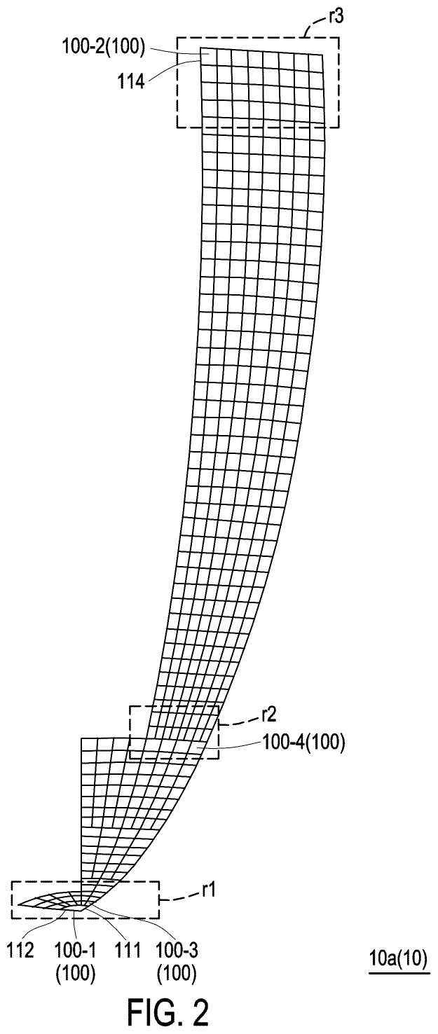

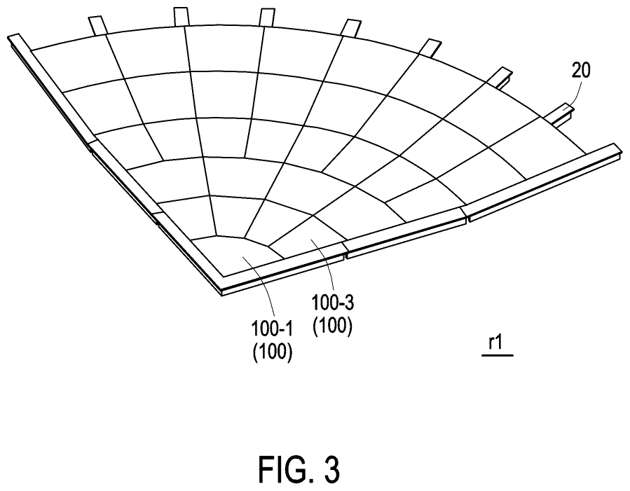

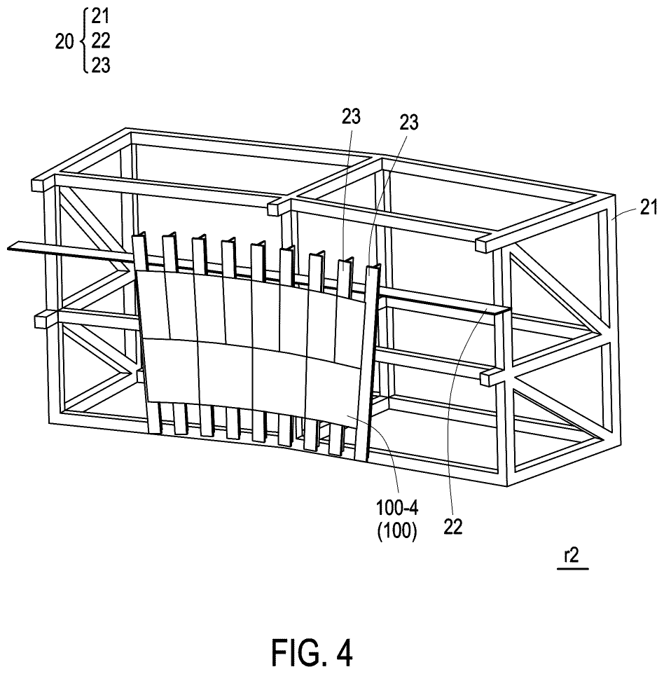

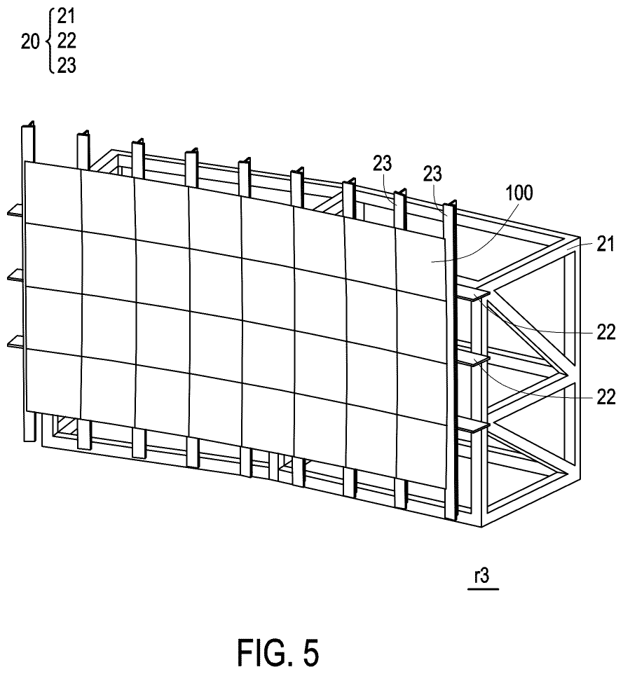

FIG. 1 is a schematic diagram of a display apparatus 10 of an embodiment of the disclosure. FIG. 2 is an enlarged schematic diagram of a portion 10a of the display apparatus 10 of FIG. 1. FIG. 3 is an enlarged schematic diagram of part r1 of a portion 10a of the display apparatus 10 of FIG. 2. FIG. 4 is an enlarged schematic diagram of part r2 of a portion 10a of the display apparatus 10 of FIG. 2. FIG. 5 is an enlarged schematic diagram of part r3 of a portion 10a of the display apparatus 10 of FIG. 2. The support structure 20 of FIG. 3, FIG. 4, and FIG. 5 is omitted from FIG. 1 and FIG. 2.

Referring to FIG. 1 and FIG. 2, the display apparatus 10 includes multiple light-emitting element substrates 100. The light-emitting element substrates 100 are spliced into a sphere 1. The sphere 1 has multiple dummy latitudes 1a and multiple dummy meridians 1b. The sphere 1 further has a central axis 1c passing through the center of the sphere 1 and two dummy poles 1n and 1s of the sphere 1. The dummy latitudes 1a surround the dummy central axis 1c and are spaced apart from each other. The dummy meridians 1b and interlaced with the dummy latitudes 1a and spaced apart from each other. The dummy meridians 1b intersect at two opposite dummy poles 1n and 1s of the sphere 1. The sphere 1 further has a dummy equator 1d. The sphere 1 may be bisected by a dummy plane (not shown) where the dummy equator 1d is located, and the two dummy poles 1n and Is of the sphere 1 are respectively located on opposite sides of the dummy plane.

Referring to FIG. 2, FIG. 3, FIG. 4, and FIG. 5, in some embodiments, multiple light-emitting element substrates 100 may be selectively installed on the support structure 20 and spliced into the sphere 1. Referring to FIG. 1, FIG. 2, FIG. 4, and FIG. 5, for example, in some embodiments, the support structure 20 may include a main bracket 21, multiple first support members 22 substantially parallel to the dummy latitudes 1a, and multiple second support members 23 substantially parallel to the dummy meridians 1b. The first support members 22 are fixed on the main bracket 21, the second support members 23 are embedded in the first support members 22, and the light-emitting element substrates 100 may be selectively magnetically attached to the second support members 23 to be spliced into the sphere 1. However, the disclosure is not limited thereto. In other embodiments, the light-emitting element substrates 100 may also be spliced into the sphere 1 through other methods (such as but not limited to: mutual engagement).

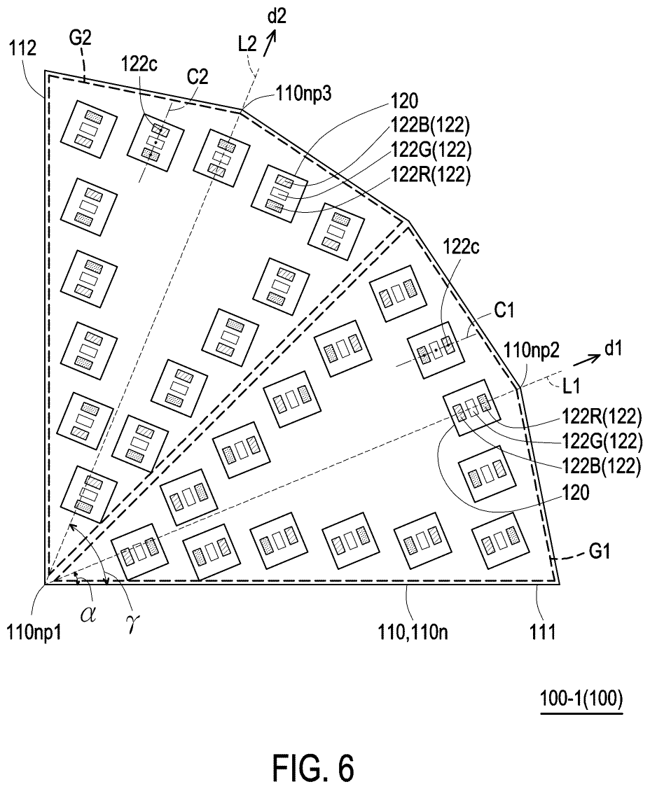

FIG. 6 is a schematic diagram of a light-emitting element substrate 100-1 of an embodiment of the disclosure. Referring to FIG. 1, FIG. 2, FIG. 3, and FIG. 6, one of the two dummy poles 1n and 1s of the sphere 1 is located in the part r1, and the light-emitting element substrate 100-1 of FIG. 6 is located in the part r1 of FIG. 2.

Referring to FIG. 2 to FIG. 6, each of the light-emitting element substrates 100 includes a base 110 and multiple pixel structures 120 disposed on the base 110. Each of the pixel structures 120 includes multiple light-emitting elements 122 for emitting different color lights. In some embodiments, the light-emitting elements 122 of each of the pixel structures 120 may include a first light-emitting element 122R, a second light-emitting element 122G, and a third light-emitting element 122B respectively configured to emit a first color light, a second color light, and a third color light. In some embodiments, the first color light, the second color light, and the third color light are, for example, red light, green light, and blue light respectively, but the disclosure is not limited thereto. In some embodiments, the light-emitting element 122 is, for example, a light-emitting diode, and the base 110 is, for example, a circuit substrate electrically connected to the light-emitting element 122, but the disclosure is not limited thereto.

Referring to FIG. 1, FIG. 2, and FIG. 6, the light-emitting element substrates 100 of the display apparatus 10 include a light-emitting element substrate 100-1. The base 110 of the light-emitting element substrate 100-1 is in an N-gonal shape 110n, where N is a positive integer greater than 4. The N-gonal shape 110n has a first edge 111 and a second edge 112. The first edge 111 and the second edge 112 are substantially parallel to two of the dummy meridians 1b of the sphere 1 respectively. A dummy reference line L1 is located between the first edge 111 and the second edge 112 and is not parallel to the first edge 111 and the second edge 112. The pixel structures 120 of the light-emitting element substrate 100-1 include a pixel structure group G1. The light-emitting elements 122 of the pixel structures 120 of the pixel structure group G1 are substantially arranged along a direction d1 parallel to the dummy reference line L1. Referring to FIG. 6, in some embodiments, a connection line C1 connecting multiple center points 122c of the light-emitting elements 122 of a pixel structure 120 of the pixel structure group G1 is substantially parallel to the dummy reference line L1.

Referring to FIG. 6, in some embodiments, the dummy reference line L2 is located between the dummy reference line L1 and the second edge 112 of the base 110 and is not parallel to the first edge 111, the second edge 112, and the dummy reference line L1. The pixel structures 120 of the light-emitting element substrate 100-1 may optionally further include another pixel structure group G2. The pixel structure group G2 is located between the pixel structure group G1 and the second edge 112 of the base 110. The light-emitting elements 122 of the pixel structures 120 of the pixel structure group G2 are substantially arranged along a direction d2 parallel to the dummy reference line L2. In some embodiments, a connection line C2 connecting multiple center points 122c of the light-emitting elements 122 of a pixel structure 120 of the pixel structure group G2 is substantially parallel to the dummy reference line L2.

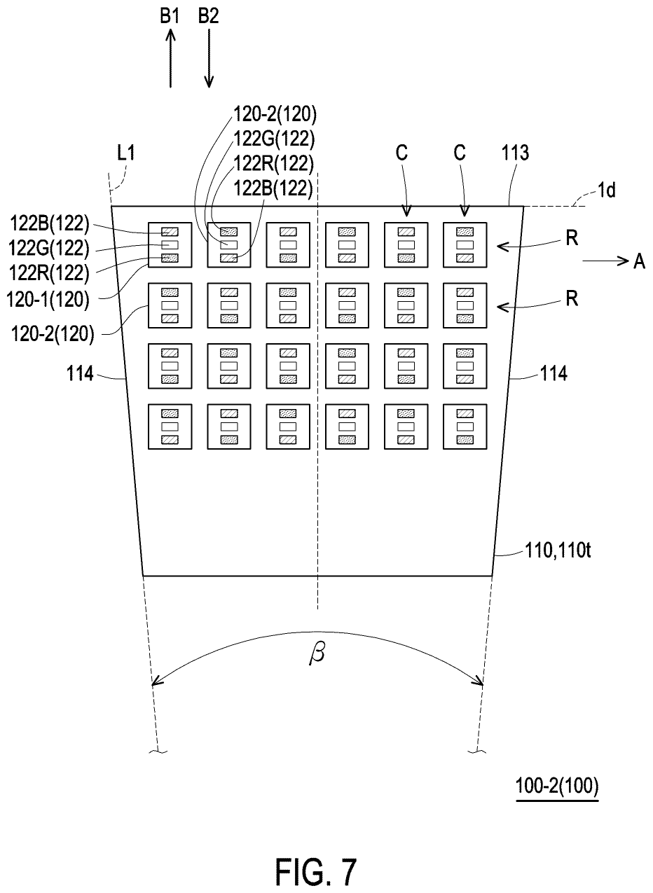

FIG. 7 is a schematic diagram of a light-emitting element substrate 100-2 of an embodiment of the disclosure. Referring to FIG. 1, FIG. 2, and FIG. 7, the dummy equator 1d of the sphere 1 passes through the part r3 of FIG. 2, and the light-emitting element substrate 100-2 of FIG. 7 is located in the part r3.

Referring to FIG. 1, FIG. 2, FIG. 6, and FIG. 7, in some embodiments, the light-emitting element substrate 100-1 is located between one of the dummy poles 1n and 1s and the dummy equator 1d. The light-emitting element substrates 100 of the display apparatus 10 further include another light-emitting element substrate 100-2. The light-emitting element substrate 100-2 is located between the light-emitting element substrate 100-1 and the dummy equator 1d. The base 110 of the light-emitting element substrate 100-2 is in a trapezoidal shape 110t. A lower base 113 of the trapezoidal shape 110t is substantially located on the dummy equator 1d, and a portion of the dummy reference line L1 substantially coincides with one lateral side 114 of the trapezoidal shape 110t.

Referring to FIG. 1, FIG. 2, FIG. 6, and FIG. 7, in some embodiments, the dummy reference line L1 and the first edge 111 of the N-gonal shape 110n include a first angle α (marked in FIG. 6). The two lateral sides 114 of the trapezoidal shape 110t include a second angle β (marked in FIG. 7), and the first angle α is an integer multiple of the second angle β. For example, in some embodiments, the second angle β is approximately 1.406°, the first angle α is approximately 22.5°, and the first angle α is approximately 16 times the second angle β. However, the disclosure is not limited thereto. The size of the second angle β and/or the multiplicative relationship between the first angle α and the second angle β may be designed differently according to actual requirements.

Referring to FIG. 6. In some embodiments, the N-gonal shape 110n has a first vertex 110np1, and the dummy reference line L1 passes through the first vertex 110np1. In some embodiments, the first vertex 110np1 is the intersection point of the first edge 111 and the second edge 112. In some embodiments, the N-gonal shape 110n further has a second vertex 110np2. The second vertex 110np2 is located opposite to the first vertex 110np1, and the dummy reference line L1 may pass through the first vertex 110np1 and the second vertex 110np2. In some embodiments, N is, for example, 6, and the N-gonal shape 110n is, for example, a hexagon, but the disclosure is not limited thereto.

Referring to FIG. 1, FIG. 2, FIG. 6, and FIG. 7, in some embodiments, the dummy reference line L2 and the first edge 111 of the N-gonal shape 110n include a third angle γ (marked in FIG. 6). The two lateral sides 114 of the trapezoidal shape 110t include a second angle β (marked in FIG. 7), and the third angle γ is an integer multiple of the second angle β. For example, in some embodiments, the second angle β is approximately 1.406°, the third angle γ is approximately 67.5°, and the third angle γ is approximately 48 times the second angle β. However, the disclosure is not limited thereto. The size of the second angle β and/or the multiplicative relationship between the third angle γ and the second angle β may be designed differently according to actual requirements.

Referring to FIG. 6, in some embodiments, the N-gonal shape 110n further has a third vertex 110np3. The third vertex 110np3 is located opposite to the first vertex 110np1 and next to the second vertex 110np2, and the dummy reference line L2 passes through the first vertex 110np1 and the third vertex 110np3.

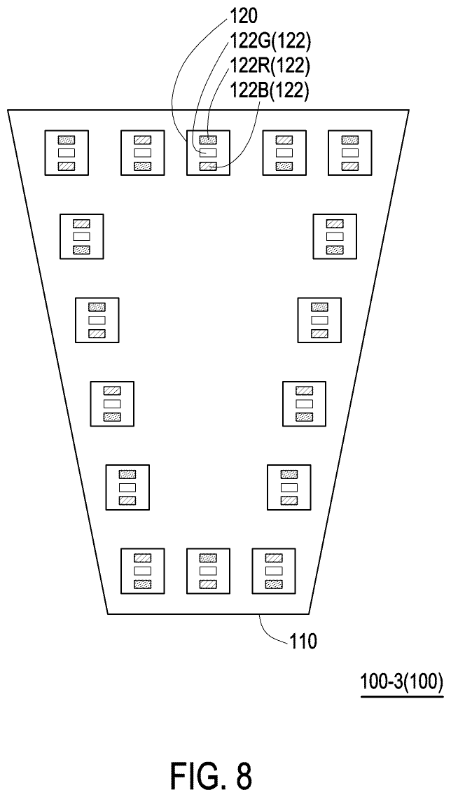

FIG. 8 is a schematic diagram of a light-emitting element substrate 100-3 of an embodiment of the disclosure. Referring to FIG. 1, FIG. 2, FIG. 3, FIG. 6, and FIG. 8, the light-emitting element substrate 100-3 of FIG. 8 is located in the part r1 of FIG. 2 and between the light-emitting element substrate 100-1 of FIG. 6 and the dummy equator 1d. The light-emitting element substrate 100-3 of FIG. 8 is spliced with the light-emitting element substrate 100-1 of FIG. 6.

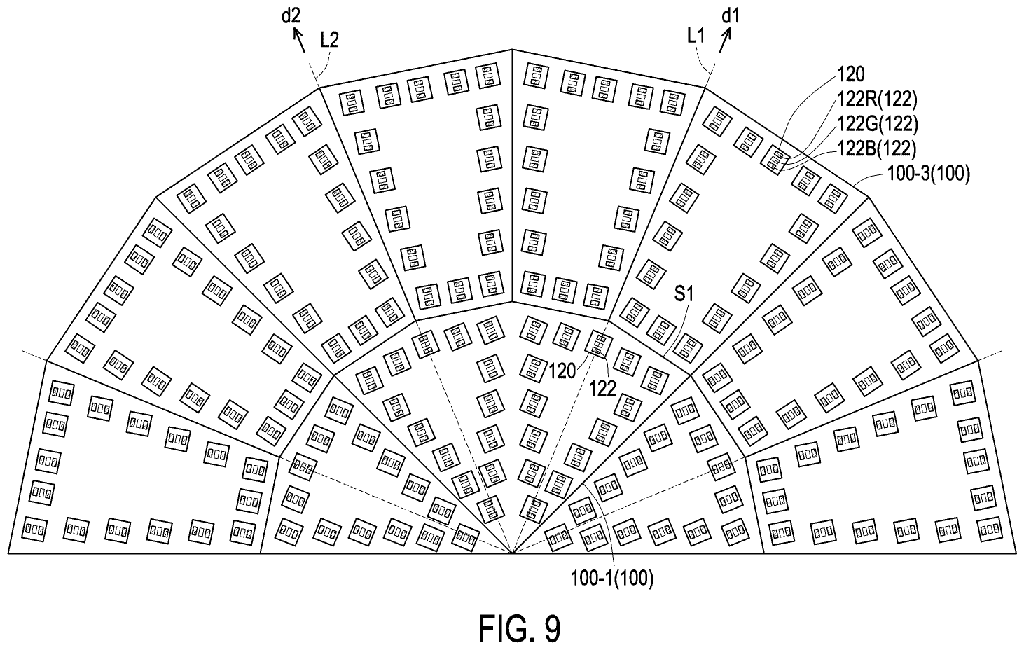

FIG. 9 is a schematic diagram of various light-emitting element substrates of an embodiment of the disclosure. In particular, FIG. 9 shows a portion of the sphere 1 (refer to FIG. 1) formed by splicing the light-emitting element substrate 100-1 of FIG. 6 and the light-emitting element substrate 100-3 of FIG. 8.

Referring to FIG. 1, FIG. 2, FIG. 3, FIG. 6, FIG. 8, and FIG. 9, the light-emitting element substrates 100 of the display apparatus 10 include a light-emitting element substrate 100-3. The light-emitting element substrate 100-3 is adjacent to the light-emitting element substrate 100-1. It is worth noting that since the light-emitting elements 122 of the pixel structures 120 of the light-emitting element substrate 100-1 are substantially arranged along the direction d1 parallel to the dummy reference line L1, the misalignment problem of the pixel structures 120 of the two adjacent light-emitting element substrates 100-1 and 100-3 at the splicing seam S1 may be alleviated, thereby improving the quality of the display apparatus 10.

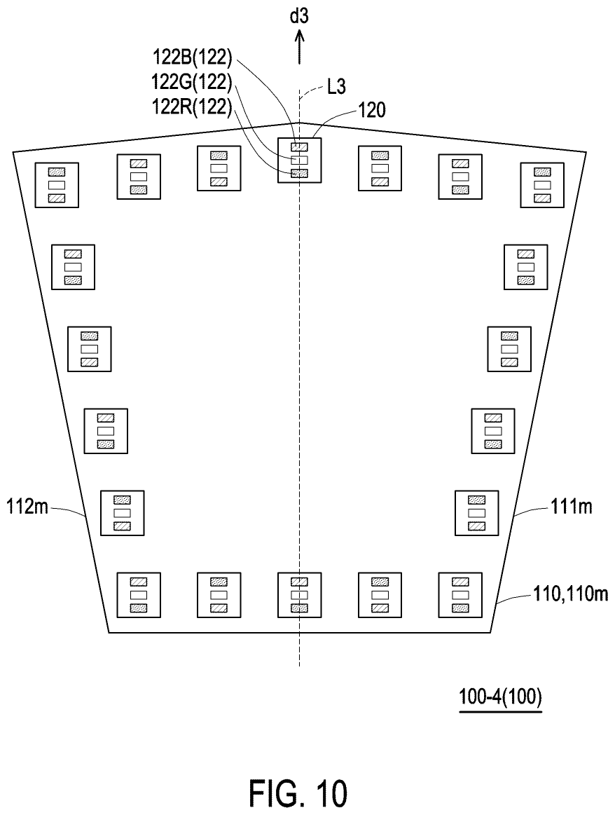

FIG. 10 is a schematic diagram of a light-emitting element substrate 100-4 of an embodiment of the disclosure. Referring to FIG. 1, FIG. 2, FIG. 4, and FIG. 10, the part r2 is located between the part r1 and the part r3, and the light-emitting element substrate 100-4 is located in part r2. The light-emitting element substrates 100 of the display apparatus 10 further include a light-emitting element substrate 100-4. The base 110 of the light-emitting element substrate 100-4 may be in an M-gonal shape 110m, where M is a positive integer greater than 4. The M-gonal shape 110m has a first edge 111m and a second edge 112m. The first edge 111m and the second edge 112m are substantially parallel to two of the dummy meridians 1b of the sphere 1 respectively. A dummy reference line L3 is located between the first edge 111m and the second edge 112m and is not parallel to the first edge 111m and the second edge 112m. The light-emitting elements 122 of the pixel structures 120 of the light-emitting element substrate 100-4 are substantially arranged along a direction d3 parallel to the dummy reference line L3. For example, in some embodiments, M is, for example, 5, and the M-gonal shape 110 m is, for example, a pentagon.

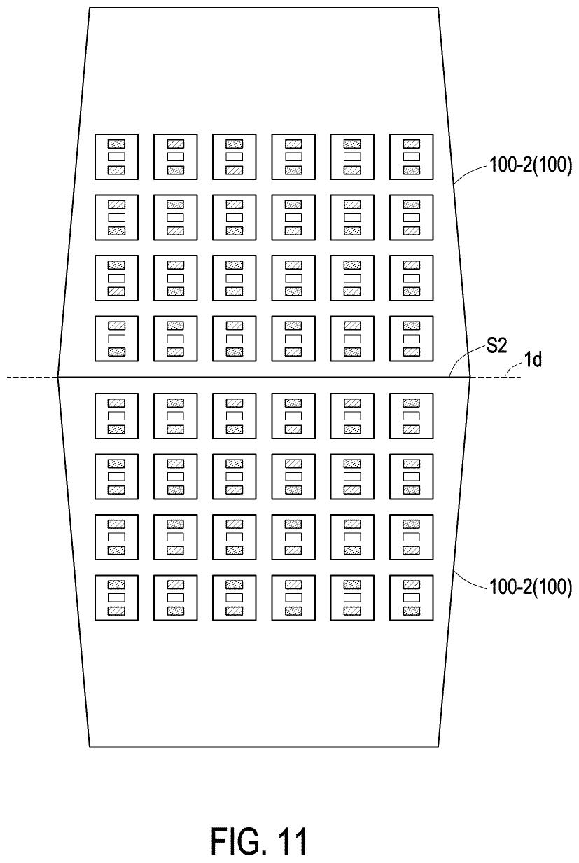

FIG. 11 is a schematic diagram of multiple light-emitting element substrates 100-2 of an embodiment of the disclosure. Referring to FIG. 1, FIG. 2, FIG. 7, and FIG. 11, the light-emitting element substrates 100 of the display apparatus 10 include multiple light-emitting element substrates 100-2. The light-emitting element substrates 100-2 may be respectively located on opposite sides of the dummy equator 1d. That is, the light-emitting element substrates 100-2 may be respectively located in the southern hemisphere and the northern hemisphere of the sphere 1. The pixel structures 120 of each of the light-emitting element substrates 100-2 include multiple first pixel structures 120-1 and multiple second pixel structures 120-2. The first light-emitting element 122R, the second light-emitting element 122G, and the third light-emitting element 122B of each of the first pixel structures 120-1 are sequentially arranged in the first meridian direction B1. The first light-emitting element 122R, the second light-emitting element 122G, and the third light-emitting element 122B of each of the second pixel structures 120-2 are sequentially arranged in the second meridian direction B2. The first meridian direction B1 and the second meridian direction B2 are substantially parallel to multiple dummy meridians 1b, and the first meridian direction B1 is opposite to the second meridian direction B2. The first pixel structures 120-1 and the second pixel structures 120-2 of the light-emitting element substrate 100-2 are arranged into multiple pixel rows R and multiple pixel columns C. The first pixel structures 120-1 and the second pixel structures 120-2 of each of the pixel rows R are alternately arranged in a latitude direction A that is substantially parallel to multiple dummy latitudes 1a, and/or the first pixel structures 120-1 and the second pixel structures 120-2 of each of the pixel column C are alternately arranged in the first meridian direction B1.

Thereby, the large viewing angle color shift problem of the display apparatus 10 may be improved. While improving the large viewing angle color shift problem, the two light-emitting element substrates 100-2 respectively disposed in the southern hemisphere and the northern hemisphere of the sphere 1 and located at the same latitude may also share the same design, without the need to separately design multiple light-emitting element substrates 100-2 located in the northern and southern hemispheres of the sphere 1. In addition, the splicing seam S2 of the two light-emitting element substrates 100-2 is not prone to abnormal conditions (e.g., the occurrence of bright lines of a specific color and/or dark lines of a specific color that are perceptible to the naked eye).

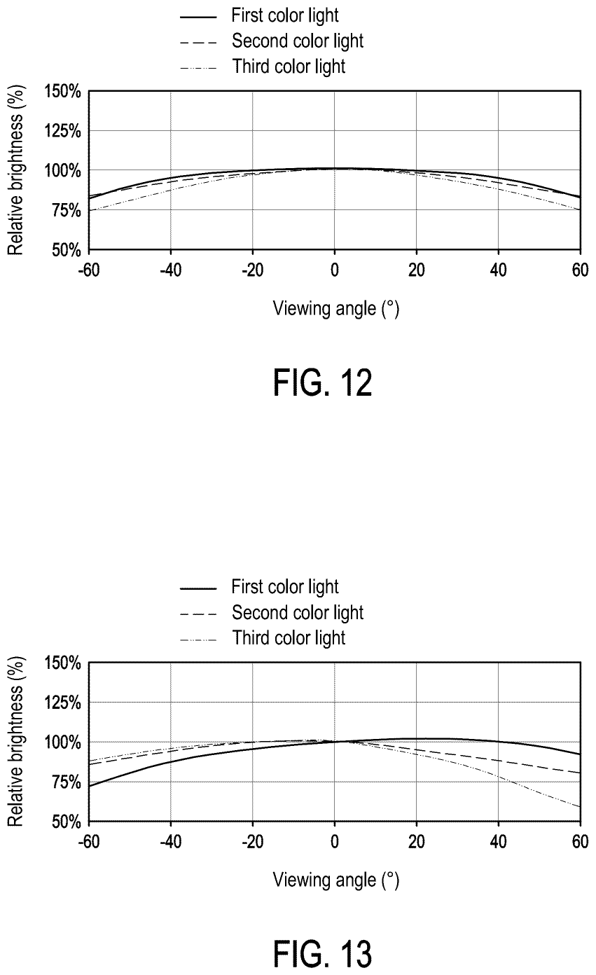

FIG. 12 shows the relative brightness of the first color light, the second color light, and the third color light at various viewing angles of the display apparatus 10 of an embodiment of the disclosure. FIG. 13 shows the relative brightness of the first color light, the second color light, and the third color light at various viewing angles of a display apparatus of a comparative example. The display apparatus (not shown) of a comparative example corresponding to FIG. 13 is similar to the display apparatus 10 of an embodiment corresponding to FIG. 12. The difference between the two is: the first light-emitting element 122R, the second light-emitting element 122G, and the third light-emitting element 122B of multiple pixel structures 120 located on the same side of the dummy equator 1d of sphere 1 are arranged along the same first meridian direction B1 or second meridian direction B2. Comparing FIG. 12 and FIG. 13, it may be seen that the display apparatus 10 according to an embodiment of the disclosure may indeed improve the color shift problem under a large viewing angle. For example, the color shift of the display apparatus of the comparative example at a top viewing angle of −60° is Δu′v′=0.016, and the color shift of the display apparatus of the comparative example at a bottom viewing angle of 60° is Δu′v′=0.026. The color shift of the display apparatus 10 of the embodiment at a top viewing angle of −60° is Δu′v′=0.009, and the color shift of the display apparatus 10 of the embodiment at a bottom viewing angle of −60° is Δu′v′=0.009.

It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

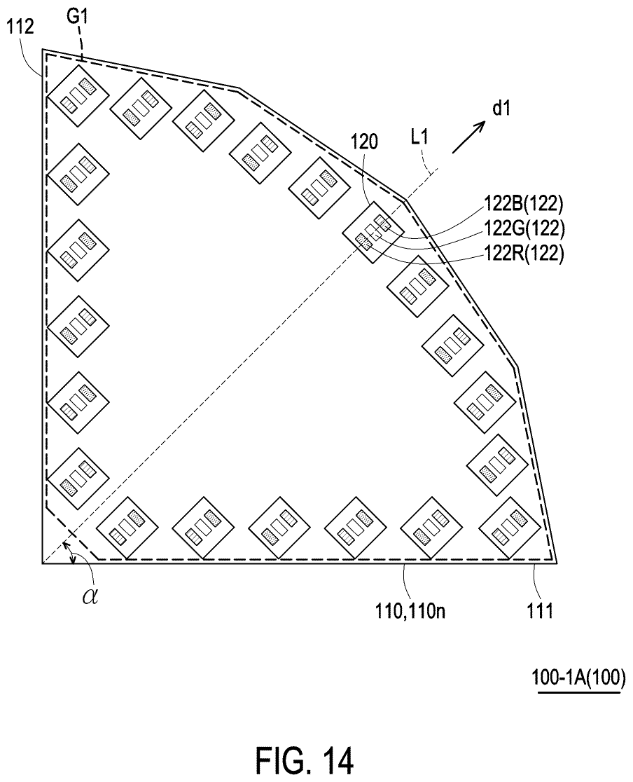

FIG. 14 is a schematic diagram of a light-emitting element substrate 100-1A of a display apparatus of another embodiment of the disclosure. The light-emitting element substrate 100-1A of FIG. 14 is similar to the light-emitting element substrate 100-1 of FIG. 6. The base 110 of the light-emitting element substrate 100-1A in FIG. 14 is also in an N-gonal shape 110n. The difference between the two is: in the embodiment of FIG. 14, the first angle α between the dummy reference line L1 and the first edge 111 of the base 110 of the light-emitting element substrate 100-1A is 45°.

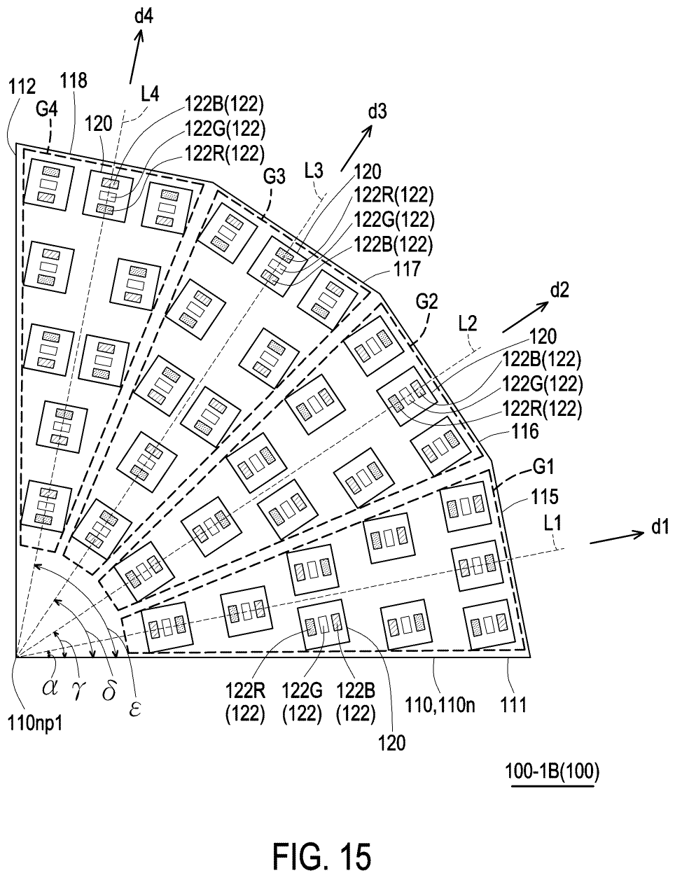

FIG. 15 is a schematic diagram of a light-emitting element substrate 100-1B of a display apparatus of yet another embodiment of the disclosure. The light-emitting element substrate 100-1B of FIG. 15 is similar to the light-emitting element substrate 100-1 of FIG. 6, the base 110 of the light-emitting element substrate 100-1B in FIG. 15 is also in an N-gonal shape 110n, and the differences between the two are as follows.

In the embodiment of FIG. 15, the N-gonal shape 110n has a third edge 115. The third edge 115 is connected between the first edge 111 and the second edge 112. The third edge 115 is disposed opposite to the first vertex 110np1, and the dummy reference line L1 passes through the first vertex 110np1 and the third edge 115. The light-emitting elements 122 of the pixel structures 120 of the pixel structure group G1 are substantially arranged along the direction d1 parallel to the dummy reference line L1.

In the embodiment of FIG. 15, the N-gonal shape 110n further has a fourth edge 116, a fifth edge 117, and a sixth edge 118 disposed opposite to the first vertex 110np1. The third edge 115, the fourth edge 116, the fifth edge 117, and the sixth edge 118 are not parallel and connected in series. The dummy reference line L2 passes through the first vertex 110np1 and the fourth edge 116. The dummy reference line L3 passes through the first vertex 110np1 and the fifth edge 117. The dummy reference line L4 passes through the first vertex 110np1 and the sixth edge 118. The pixel structures 120 of the light-emitting element substrate 100-1B further include a pixel structure group G2, a pixel structure group G3, and a pixel structure group G4 respectively corresponding to the fourth edge 116, the fifth edge 117, and the sixth edge 118. The light-emitting elements 122 of the pixel structures 120 of the pixel structure group G2 are substantially arranged along the direction d2 parallel to the dummy reference line L2. The light-emitting elements 122 of the pixel structures 120 of the pixel structure group G3 are substantially arranged along the direction d3 parallel to the dummy reference line L3. The light-emitting elements 122 of the pixel structures 120 of the pixel structure group G4 are substantially arranged along the direction d4 parallel to the dummy reference line LA.

The dummy reference line L1 and the first edge 111 of the N-gonal shape 110n include a first angle α. The dummy reference line L2 and the first edge 111 of the N-gonal shape 110n include a third angle γ. The dummy reference line L3 and the first edge 111 of the N-gonal shape 110n include a fourth angle δ. The dummy reference line L4 and the first edge 111 of the N-gonal shape 110n include a fifth angle ε. The first angle α, the third angle γ, the fourth angle δ, and the fifth angle ε are all integer multiples of the second angle β. For example, in some embodiments, the first angle α is approximately 11.25°, the third angle γ is approximately 33.75°, the fourth angle δ is approximately 56.25°, and the fifth angle ε is approximately 78.75°.

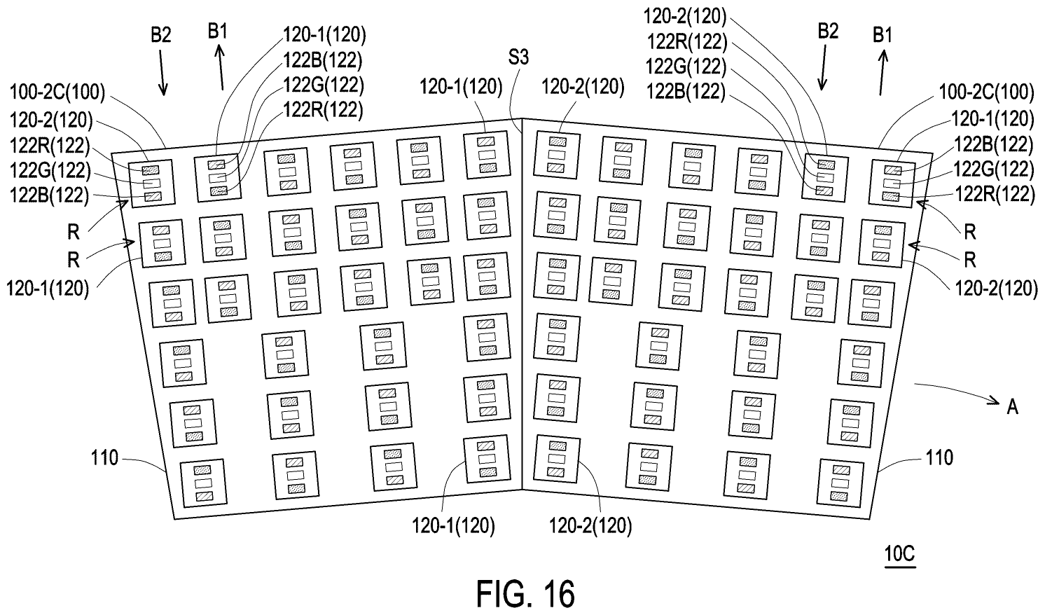

FIG. 16 is a schematic diagram of multiple light-emitting element substrates of a display apparatus of yet another embodiment of the disclosure. Referring to FIG. 16, the light-emitting element substrates 100 of the display apparatus 10C include multiple light-emitting element substrates 100-2C spliced in the latitude direction A. The base 110 of each of the light-emitting element substrates 100-2C is in a non-rectangular shape. The pixel structures 120 of each of the light-emitting element substrates 100-2C includes multiple first pixel structures 120-1 and multiple second pixel structures 120-2. The first light-emitting element 122R, the second light-emitting element 122G, and the third light-emitting element 122B of each of the first pixel structures 120-1 are sequentially arranged in the first meridian direction B1. The first light-emitting element 122R, the second light-emitting element 122G, and the third light-emitting element 122B of each of the second pixel structures 120-2 are sequentially arranged in the second meridian direction B2. The first meridian direction B1 and the second meridian direction B2 are substantially parallel to the dummy meridians 1b (referring to FIG. 1), and the first meridian direction B1 is opposite to the second meridian direction B2. The first pixel structures 120-1 and the second pixel structures 120-2 of each of the light-emitting element substrates 100-2C are arranged into multiple pixel rows R. The first pixel structures 120-1 and the second pixel structures 120-2 of each of the pixel rows R are alternately arranged in the latitude direction A that is substantially parallel to the dummy latitudes 1a (referring to FIG. 1), and the sum of the number of the first pixel structures 120-1 and the number of the second pixel structures 120-2 in each of the pixel rows R is an even number.

In this way, when two adjacent light-emitting element substrates 100-2C are spliced into a portion of the sphere 1 (referring to FIG. 1), in the portion of sphere 1, the first pixel structures 120-1 and the second pixel structures 120-2 of the two spliced pixel rows R of the two adjacent light-emitting element substrates 100-2C may be maintained as alternately arranged in the latitude direction A, such that the situation where two pixel structures 120 closest to the splicing seam S3 and located on either side of the splicing seam S3 are either both first pixel structures 120-1 or both second pixel structures 120-2 does not occur. This may prevent the situation where the display apparatus 10C exhibits a different arrangement sequence of multiple pixel structures at the splicing seam S3 compared to that on the element substrate.

What is claimed is:

1. A display apparatus, comprising:
a plurality of light-emitting element substrates, spliced into a sphere, wherein the sphere has a plurality of dummy latitudes and a plurality of dummy meridians, and each of the light-emitting element substrates comprises:
a base; and
a plurality of pixel structures, disposed on the base, wherein each of the pixel structures comprises a plurality of light-emitting elements for emitting different color lights;
the light-emitting element substrates comprising a first light-emitting element substrate, wherein the base of the first light-emitting element substrate is in an N-gonal shape, N is a positive integer greater than 4, the N-gonal shape has a first edge and a second edge, the first edge and the second edge are substantially parallel to the dummy meridians of the sphere respectively, a dummy reference line is located between the first edge and the second edge and is not parallel to the first edge and the second edge, the pixel structures of the first light-emitting element substrate comprise a pixel structure group, the light-emitting elements of the pixel structures of the pixel structure group are substantially arranged along a direction parallel to the dummy reference line.

2. The display apparatus according to claim 1, wherein a connection line connecting a plurality of center points of the light-emitting elements of one of the pixel structure of the pixel structure group is substantially parallel to the dummy reference line.

3. The display apparatus according to claim 1, wherein the N-gonal shape has a first vertex, and the dummy reference line passes through the first vertex.

4. The display apparatus according to claim 3, wherein the first vertex is an intersection point of the first edge and the second edge, the N-gonal shape further has a second vertex, the second vertex is located opposite to the first vertex, and the dummy reference line passes through the first vertex and the second vertex.

5. The display apparatus according to claim 3, wherein the N-gonal shape further has a third edge, the third edge is connected between the first edge and the second edge, the third edge is disposed opposite to the first vertex, and the dummy reference line passes through the first vertex and the third edge.

6. The display apparatus according to claim 1, wherein the sphere further has a dummy pole, the dummy latitudes intersect at the dummy pole, the sphere further has a dummy equator, the first light-emitting element substrate is located between the dummy pole and the dummy equator, the light-emitting element substrates further comprise a second light-emitting element substrate, the second light-emitting element substrate is located between the first light-emitting element substrate and the dummy equator, the base of the second light-emitting element substrate is in a trapezoidal shape, a lower base of the trapezoidal shape is substantially located on the dummy equator, and a portion of the dummy reference line substantially coincides with a lateral side of the trapezoidal shape.

7. The display apparatus according to claim 6, wherein the dummy reference line and the first edge of the N-gonal shape comprise a first angle, two lateral sides of the trapezoidal shape comprise a second angle, and the first angle is an integer multiple of the second angle.

8. The display apparatus according to claim 1, wherein the light-emitting elements of each of the pixel structures of each of the light-emitting element substrates comprise a first light-emitting element and a second light-emitting element, the first light-emitting element and the second light-emitting element are configured to emit a first color light and a second color light respectively;
the light-emitting element substrates comprise a second light-emitting element substrate, the pixel structures of the second light-emitting element substrate comprise a plurality of first pixel structures and a plurality of second pixel structures, the first light-emitting element and the second light-emitting element of each of the first pixel structures are arranged sequentially in a first meridian direction, the first light-emitting element and the second light-emitting element of each of the second pixel structure are arranged sequentially in a second meridian direction, the first meridian direction and the second meridian direction are substantially parallel to the dummy meridians, and the first meridian direction is opposite to the second meridian direction;
the first pixel structures and the second pixel structures of the second light-emitting element substrate are arranged into a plurality of pixel rows, a plurality of first pixel structures and a plurality of second pixel structures in each of the pixel rows are alternately arranged in a latitude direction that is substantially parallel to the dummy latitudes, and a sum of a number of the first pixel structures and a number of the second pixel structures in each of the pixel rows is an even number.

9. The display apparatus according to claim 8, wherein the first pixel structures and the second pixel structures of the second light-emitting element substrate are arranged in a plurality of pixel columns, a plurality of first pixel structures and a plurality of second pixel structures in each of the pixel columns are alternately arranged in the first meridian direction.

10. A display apparatus, comprising:
a plurality of light-emitting element substrates, spliced into a sphere, wherein the sphere has a plurality of dummy latitudes and a plurality of dummy meridians, and each of the light-emitting element substrates comprises:
a base; and
a plurality of pixel structures, disposed on the base, wherein each of the pixel structures comprises a first light-emitting element and a second light-emitting element respectively configured to emit a first color light and a second color light;
the light-emitting element substrates comprising a first light-emitting element substrate, wherein the pixel structures of the first light-emitting element substrate comprise a plurality of first pixel structures and a plurality of second pixel structures, the first light-emitting element and the second light-emitting element of each of the first pixel structures are arranged sequentially in a first meridian direction, the first light-emitting element and the second light-emitting element of each of the second pixel structures are arranged sequentially in a second meridian direction, the first meridian direction and the second meridian direction are substantially parallel to the dummy meridians, and the first meridian direction is opposite to the second meridian direction;
the first pixel structures and the second pixel structures of the first light-emitting element substrate are arranged into a plurality of pixel rows, a plurality of first pixel structures and a plurality of second pixel structures in each of the pixel rows are alternately arranged in a latitude direction that is substantially parallel to the dummy latitudes, and a sum of a number of the first pixel structures and a number of the second pixel structures in each of the pixel rows is an even number.

11. The display apparatus according to claim 10, wherein the first pixel structures and the second pixel structures of the first light-emitting element substrate are arranged into a plurality of pixel columns, a plurality of first pixel structures and a plurality of second pixel structures in each of the pixel columns are alternately arranged in the first meridian direction.

12. The display apparatus according to claim 10, wherein the base of the first light-emitting element substrate is in a non-rectangular shape.
